(19) United States
(12) Patent Application Publication
(10) Pub. No.: US 2026/0304761 A1
(43) Pub. Date: Oct. 1, 2026

(54) ELECTRONIC DEVICE

(71) Applicant: STMicroelectronics International N.V., Geneva (CH)

(72) Inventors: Julien Delalleau, La Cadière d'Azur (FR); Madjid Akbal, Trets (FR); Khaled Alkema, Marseille (FR)

(21) Appl. No.: 19/633,414

(22) Filed: Mar. 30, 2026

(30) Foreign Application Priority Data
Mar. 31, 2025 (FR) 2503303

(51) Int. Cl. H10B 41/30

(52) U.S. Cl. CPC H10B 41/30

(57) ABSTRACT

An embodiment device includes at least one memory cell. The memory cell includes an active area made of a semiconductor material. The active area includes source and drain regions. The memory cell includes a first selection gate made of a semiconductor material. The first selection gate extends parallel to the active area. The first selection gate is separated from the active area by a first layer made of a dielectric material. The memory cell includes a second measurement gate. The second measurement gate rests on the source and drain regions and on the first selection gate.

### CROSS-REFERENCE TO RELATED APPLICATIONS

This application claims the priority benefit of French patent application number FR 2503303, filed on Mar. 31, 2025, entitled “Dispositif électronique”, which is hereby incorporated by reference.

### TECHNICAL FIELD

The present disclosure generally concerns electronic devices and their manufacturing methods, and in particular devices comprising a memory and their manufacturing methods.

### BACKGROUND

There exist many types of memory cells. Among these different types of memory cells, there exist memory cells called EEPROM (Electrically-Erasable Programmable Read-Only Memory). An EEPROM-type memory cell is a non-volatile type of memory.

### SUMMARY

An embodiment provides a device including at least one memory cell. The memory cell includes an active area made of a semiconductor material. The active area includes source and drain regions. The memory cell includes a first selection gate made of a semiconductor material. The first selection gate extends parallel to the active area. The first selection gate is separated from the active area by a first layer made of a dielectric material. The memory cell includes a second measurement gate. The second measurement gate rests on the source and drain regions and on the first selection gate.

Another embodiment provides a device including a support made of a semiconductor material. The device includes a semiconductor region disposed on the support. The semiconductor region includes a lower portion and an upper portion extending from the lower portion. The upper portion forms a wall extending in a first direction. The device includes a dielectric layer surrounding side walls of the upper portion. The device includes a trench extending through the dielectric layer, the lower portion, and into the support. The trench includes a core made of a semiconductor material and a sheath made of a dielectric material covering a lower surface and lateral surfaces of the core. The trench extends parallel to the upper portion. The device includes at least two memory cells. Each memory cell includes source and drain regions disposed in the upper portion. The source and drain regions are doped with a conductivity type opposite to a conductivity type of the semiconductor region. Each memory cell includes a gate disposed on the upper portion and on the trench. The gate includes a first dielectric layer in contact with an upper surface of the upper portion and an upper surface of the trench. The gate includes a floating gate layer made of a semiconductor material disposed on the first dielectric layer. The gate includes a second dielectric layer disposed on the floating gate layer. The gate includes a contact gate layer made of a conductive or semiconductor material disposed on the second dielectric layer. The at least two memory cells share a common source or drain region. The core of the trench is configured to be biased during programming steps of the at least two memory cells.

Another embodiment provides a method of manufacturing a device including at least one memory cell. The method includes forming an active area made of a semiconductor material. The active area includes source and drain regions. The method includes forming a first selection gate made of a semiconductor material. The first selection gate extends parallel to the active area. The first selection gate is separated from the active area by a first layer made of a dielectric material. The method includes forming a second measurement gate. The second measurement gate rests on the source and drain regions and on the first selection gate.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1, which includes FIGS. 1A, 1B, 1C, 1D, shows an embodiment of a device comprising a memory;

FIG. 2 shows a three-dimensional view of the embodiment of FIG. 1;

FIG. 3 shows an operating mode of the device of FIGS. 1 and 2;

FIG. 4, FIG. 5, FIG. 6, FIG. 7, FIG. 8, FIG. 9, and FIG. 10 show an embodiment of a method of manufacturing the device of FIGS. 1 and 2; and

FIG. 11 shows a variant of the embodiment of FIGS. 1 and 2.

### DETAILED DESCRIPTION OF ILLUSTRATIVE EMBODIMENTS

An embodiment provides a device comprising at least one memory cell, the memory cell comprising:-an active area, made of a semiconductor material, comprising source and drain regions;-a first selection gate made of a semiconductor material extending parallel to the active area, the first selection gate being separated from the active area by a first layer made of a dielectric material; and -a second measurement gate resting on the source and drain regions and on the first gate.

Another embodiment provides a method of manufacturing a device comprising at least one memory cell, the method comprising:-the forming of an active area, made of a semiconductor material, comprising source and drain regions;-the forming of a first selection gate made of a semiconductor material extending parallel to the active area, the first selection gate being separated from the active area by a first layer made of a dielectric material; and -the forming of a second measurement gate resting on the source and drain regions and on the first selection gate.

According to an embodiment, the first selection gate is made of polysilicon.

According to an embodiment, the second measurement gate comprises a second layer made of a dielectric material, a first layer made of a semiconductor material, a third layer made of an insulating material, and a second layer made of a semiconductor material.

According to an embodiment, the first selection gate and the active area are separated only by the first layer made of a dielectric material.

According to an embodiment, the second layer made of a dielectric material is in contact with the first selection gate and with the active area.

According to an embodiment, the memory cells are arranged in an array of rows and columns.

According to an embodiment, the second semiconductor layer is common to a plurality of memory cells in a same row.

According to an embodiment, the first selection gate is common to a plurality of memory cells in a same column.

According to an embodiment, the device comprises at least two memory cells having a source or drain region in common.

According to an embodiment, the method comprises the forming of a cavity at the location of the first selection gate and the forming of the first layer made of a dielectric material along the side walls and the bottom of the cavity by oxidation.

According to an embodiment, voltages are applied to the memory cell in such a way that electrons are transferred, by Fowler-Nordheim tunneling effect, from the second gate to the first selection gate.

According to an embodiment, voltages are applied to the memory cell in such a way that electrons are transferred, by Fowler-Nordheim tunneling effect, from the first selection gate to the second measurement gate.

According to an embodiment, voltages are applied to the memory cell in such a way that a current is formed between the source and drain regions of the cell.

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

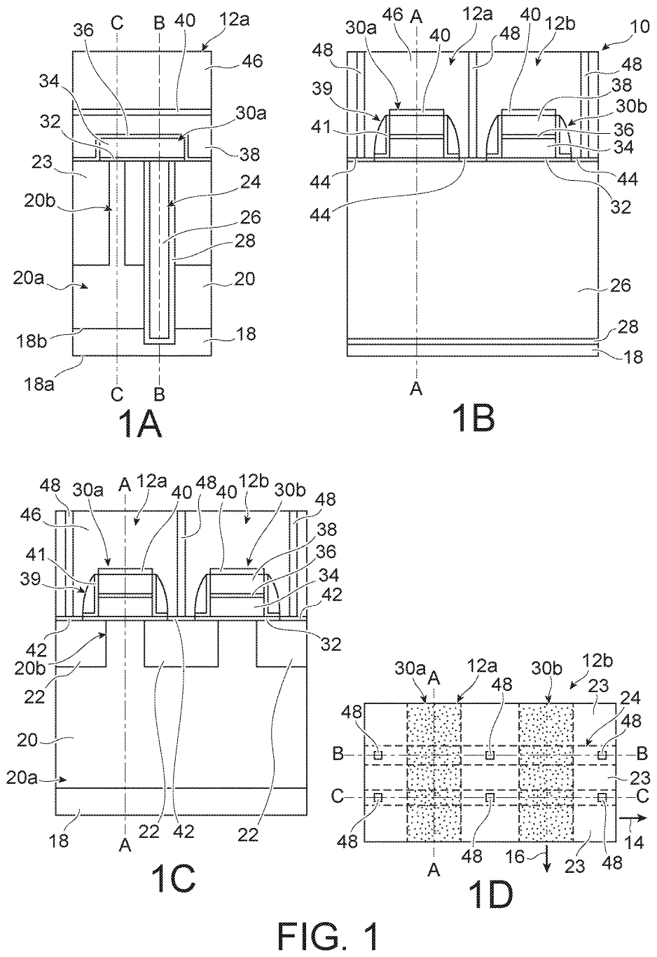

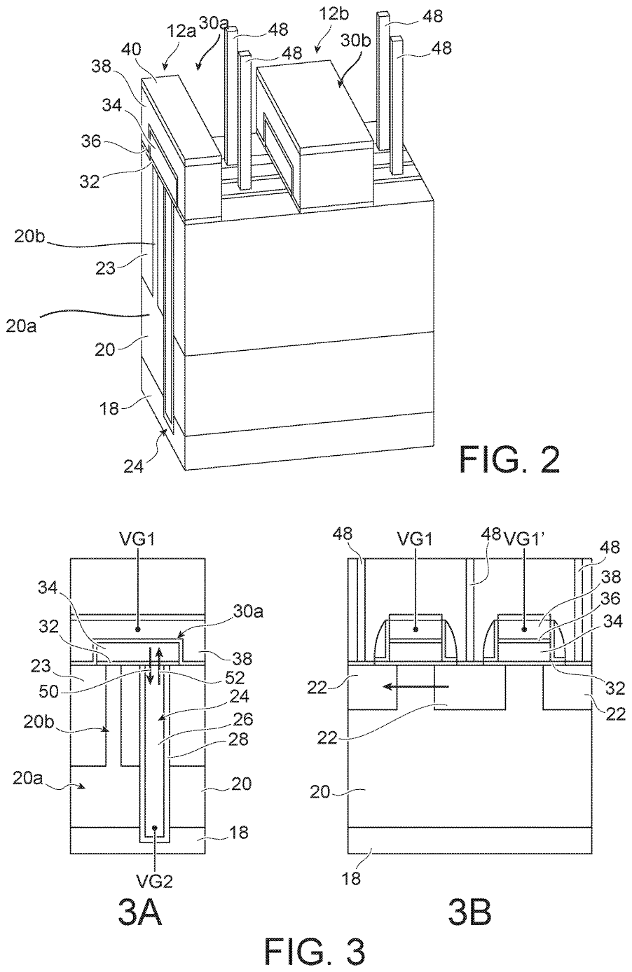

FIG. 1 shows an embodiment of a device 10 comprising a memory. More specifically, FIG. 1 comprises three cross-section views 1A, 1B, 1C of device 10, respectively along planes A-A, B-B, C-C, a top view 1D. Planes B-B and C-C are parallel to each other. Plane A-A is perpendicular to planes B-B and C-C. Elements of view 1D, shown in dotted lines, correspond to elements located in the other planes. FIG. 2 shows a three-dimensional view of the embodiment of FIG. 1.

FIGS. 1 and 2 show an assembly of two memory cells 12a and 12b. Each memory cell 12a or 12b may contain one data item. Device 10 preferably comprises a memory region comprising a plurality of assemblies such as that shown in FIGS. 1 and 2. For example, the memory region comprises an array of memory cells 12a, 12b, preferably only memory cells 12a, 12b, forming rows and columns.

Preferably, the cells 12a, 12b of a same assembly are aligned in a first direction, corresponding to a direction orthogonal to the plane of view 1A. The first direction is in the planes of views 1B and 1C. More specifically, the first direction corresponds to the horizontal direction of views 1B and 1C. The first direction is represented by an arrow 14, in view 1D. The first direction corresponds, for example, to the direction of the rows of the array of memory cells.

A second direction corresponds, for example, to the direction of the columns of the array of memory cells. The second direction is represented by an arrow 16 in view 1D. The second direction is perpendicular to the first direction in the plane of view 1D.

Preferably, the first direction corresponds to the bit line and the second direction corresponds to the word line.

Device 10 comprises a support 18. Support 18 is, for example, a semiconductor substrate. Support 18 is for example made of silicon, for example of undoped silicon or P-doped silicon. Support 18 comprises a lower surface and an upper surface.

Device 10 further comprises a region 20. Region 20 is a semiconductor region. Region 20 is for example made of silicon. Region 20 is, for example, P-type doped. Region 20 is for example a doped region of support 18. Region 20 rests on support 18, more specifically on the upper surface of support 18. Region 20 comprises a lower portion 20a and an upper portion 20b.

The lower portion 20a extends over, and is preferably in contact with, support 18. Portion 20a has, for example, top and bottom surfaces parallel to each other and planar. The lower portion 20a is preferably common to all memory cells 12a, 12b. The upper portion 20b extends from, and is in contact with, the upper surface of portion 20a. Portion 20b forms a wall extending in the first direction.

Portions 20a and 20b are made of the same material, with the same doping type. Preferably, portions 20a and 20b are doped with the same dopants. Preferably, the dopant concentration of portion 20a is substantially equal to the dopant concentration of portion 20b.

The device comprises regions 22. More specifically, each assembly of cells 12a, 12b comprises three regions 22. Regions 22 are made of a semiconductor material, preferably of the same material as region 20, for example of silicon. Regions 22 are doped with the conductivity type opposite to the conductivity type of region 20. For example, regions 22 are N-type doped. For example, regions 22 are doped portions of support 18, for example doped regions of region 20.

Regions 22 are located in the upper portion of region 20. More specifically, regions 22 are located at the level of the upper surface of the upper portion 20b of region 20. Thus, the upper surfaces of regions 22 and of the upper portion of region 20 are coplanar. Regions 22 are separated from one another by portions of region 20. Regions 22 are aligned in the first direction. Thus, one of the three regions 22 is located between the other two regions 22 of the assembly. The three regions 22 of the assembly illustrated in FIGS. 1 and 2 can thus be observed in view 1C.

Portion 20b is surrounded by a layer 23 made of a dielectric material, for example of silicon oxide. More specifically, the side walls of portion 20b are covered by layer 23. The lower surface of portion 20b is in contact with portion 20a. The upper surface of portion 20b is coplanar with the upper surface of layer 23.

The assembly of cells 12a, 12b further comprises a trench 24. Trench 24 comprises a core 26, for example made of a semiconductor material, for example of polysilicon, and a sheath 28 made of a dielectric material. Sheath 28 preferably covers the lower surface and the lateral surfaces of core 26.

Trench 24 extends, for example, from the upper surface of layer 23 to a level located in support 18. Trench 24 extends in layer 23. Trench 24 thus extends through layer 23, lower portion 20a and extends, for example, into part of support 18. Trench 24 extends, for example, along a height greater than the height of region 20.

Trench 24 extends parallel to portion 20b. Thus, trench 24 does not extend through, and is not in contact with, portion 20b. Trench 24, and in particular sheath 28, is separated from portion 20b by a portion of layer 23. Trench 24 is, for example, common to all the assemblies of memory cells in the same row, that is, associated with the same bit line.

Each memory cell 12a, 12b comprises a gate 30a, 30b. More specifically, memory cell 12a comprises a gate 30a and memory cell 12b comprises a gate 30b. Each gate 30a, 30b comprises a stack of layers 32, 34, 36, 38. Preferably, the gates of memory cells 12a and 12b are made of the same materials. For example, the layers 32, 34, 36, 38 of cell 12a are made of the same materials as the layers 32, 34, 36, 38 of cell 12b.

The layer 32 of each gate 30a, 30b is made of a dielectric material, for example of silicon oxide. Layer 32 forms a gate insulator. Layer 32 extends on top of, and is preferably in contact with, the upper surface of portion 20b, of trench 24, and of layer 23. More specifically, layer 32 partially covers two of the regions 22 of the assembly of cells 12a, 12b, and the portion of layer 23 located between said regions 22. Preferably, among the three regions 22 of each assembly of cells 12a, 12b, two of regions 22 are partially covered by only one of the two gates, and the region 22 located between said two regions is partially covered by the two gates 30a, 30b. Layer 32 further covers a portion of trench 24 and the portion of layer 23 located between said portion of trench 24 and regions 22.

Each layer 32 is preferably specific to a single cell 12a, 12b. Thus, each cell 12a or 12b of each assembly of cells 12a, 12b preferably comprises a layer 32 separate from the other layers 32.

The layer 34 of each gate 30a, 30b is made of a semiconductor material, for example of polysilicon. Layer 34 extends on top of, and is preferably in contact with, layer 32. Preferably, layer 34 extends only over layer 32. Layer 34 forms a floating gate. For example, in the plane of view 1A, that is, in the second direction 16, the dimensions of layer 34 are substantially equal to the dimensions of layer 32. For example, in the plane of view 1B or of view 1C, that is, in the first direction 14, the dimensions of layer 34 are smaller than the dimensions of layer 32.

Each layer 34 is preferably specific to a single cell 12a, 12b. Thus, each cell 12a or 12b of each cell assembly 12a, 12b preferably comprises a layer 34 separate from the other layers 34.

The layer 36 of each gate 30a, 30b is, for example, made of a dielectric material, for example of silicon oxide, or of a stack of layers made of dielectric materials, for example a stack of a silicon oxide layer, a silicon nitride layer, and a silicon oxide layer. Layer 36 forms a gate insulator. Layer 36 extends on top of, and is preferably in contact with, the upper surface of layer 34. For example, in the plane of view 1B or of view 1C, that is, in the first direction 14, the dimensions of layer 36 are substantially equal to the dimensions of layer 34, that is, equal to the dimensions of layer 32. For example, in the plane of view 1A, that is, in the second direction 16, the dimensions of layer 36 are greater than the dimensions of layer 32. Preferably, in the plane of view 1A, layer 36 extends on top of, and is preferably in contact with, the side walls of layers 32 and 34 and the upper surface of the portions of layer 23 located between the gates of the cells of the different bit lines.

Each layer 36 is, for example, common to a plurality of gates, preferably common to a plurality of gates of a same word line. Thus, the layers 36 of the cells of a word line, extending in the second direction 16, preferably comprise a same layer 36. The layers 36 of the cells of a same bit line are preferably separate from one another. In particular, the layers 36 of the gates 30a, 30b of an assembly of cells 12a, 12b are distinct and separate from each other.

The layer 38 of each gate 30a, 30b is made of a conductive or semiconductor material, such as polysilicon. Layer 38 forms a contact gate. Layer 38 extends on top of, and is preferably in contact with, the upper surface of layer 36. For example, in the plane of view 1B or of view 1C, that is, in the first direction 14, the dimensions of layer 38 are substantially equal to the dimensions of layer 36, that is, equal to the dimensions of layer 32. For example, in the plane of view 1A, that is, in the second direction 16, the dimensions of layer 38 are greater than the dimensions of layer 32. Preferably, in the plane of view 1A, layer 38 extends on top of, and is preferably in contact with, the upper surface of layer 36, preferably the entire upper surface of layer 36.

Each layer 38 is, for example, common to a plurality of gates, preferably common to a plurality of gates of a same word line. Thus, the layers 38 of the cells of a word line, extending in the second direction 16, preferably comprise a same layer 38. The layers 38 of the cells of a same bit line are preferably separate from one another. In particular, the layers 38 of the gates 30a, 30b of an assembly of cells 12a, 12b are distinct and separate from each other.

Each cell 12a, 12b comprises, for example, spacers 39 and layers 41 made of a dielectric material covering a portion of the upper surface of layer 32 and the side walls of layers 34, 36, 38 extending in planes parallel to the plane of view 1A.

Each cell 12a, 12b, for example, comprises a layer 40 of metal silicide. The layer 40 of each cell rests on, and is preferably in contact with, the upper surface of layer 38. Each layer 40 is preferably located opposite the layers 30 and 32 of cell 12a, 12b.

Each assembly of two cells 12a and 12b further comprises three metal silicide layers 42 and at least one metal silicide layer 44. In FIGS. 1 and 2, the embodiment comprises three layers 44. Layers 42 and 44 are, for example, made of the same material as layers 40. Each layer 42 rests on, and is preferably in contact with, a region 22. Thus, each region 22 is partially covered by a layer 42. Layers 44 rest on, and are preferably in contact with, the core 26 of trench 24.

The device further comprises a layer 46 made of an insulating material, for example of silicon oxide. Layer 46 covers the structure of the device. In particular, layer 46 covers the cells 12a, 12b, preferably all the cells 12a, 12b, and in particular the gates 30a, 30b of all the cells 12a, 12b.

The device further comprises conductive vias 48. Vias 48 are made of a conductive material, for example of metal. Vias 48 extend through layer 46 so as to reach layers 42 and 44. The device further comprises vias, not shown, for example identical to vias 48, extending through layer 46 so as to reach layers 40.

Regions 22 thus form source and drain regions and may be biased in memory cell programming steps. Similarly, the core 26 of trench 24 forms a back gate common to the cells 12a, 12b of the assembly, and may be biased in memory cell programming steps. Layers 38 form front gates and may be biased in memory cell programming steps.

FIG. 3 shows an operating mode of the device of FIGS. 1 and 2. More specifically, FIG. 3 comprises a view 3A illustrating steps of writing and erasing of a data item in a memory cell such as those shown in FIG. 1, and comprises a view 3B illustrating a memory cell reading step.

View 3A is a cross-section view of the device 10 of FIG. 1 along the cross-section plane of view 1A. View 2A includes an arrow 50 pointing from the layer 34 to the core 26 of a memory cell 12a or 12b, illustrating a step of writing of a data item into said cell 12a, 12b. View 3A comprises an arrow 52 pointing from the core 26 to the layer 34 of a memory cell 12a or 12b and illustrating a step of erasing of a data item from said cell 12a, 12b.

During the step of writing into a memory cell 12a, 12b, voltages are applied to said memory cell so that electrons are transferred, by Fowler-Nordheim tunneling effect, from layer 34 to the core 26 where they are stored.

A voltage VG1 is applied to the front gate of the cell into which the data item is written during this step. In other words, voltage VG1 is applied to the layer 38 of the gate 30a or 30b of the memory cell 12a, 12b into which the data item is written during this step. Similarly, a voltage VG2 is applied to the front gate of the cell into which the data item is written during this step. In other words, voltage VG2 is applied to the core 26 of the trench 24 of the memory cell 12a, 12b into which the data item is written during this step. Further, a voltage VG1′ is applied to the front gate of the other memory cell in the assembly of cells 12a, 12b.

Voltages VG1 and VG1′ are, for example, during the write step, negative values. During the write step, the value of voltage VG1′ is, for example, greater than the value of voltage VG1. For example, voltage VG1′ during the write step is for example in the range from −5 V to −1 V, for example substantially equal to −1.4 V. For example, voltage VG1 during the write step is for example in the range from −10 V to −5 V, for example substantially equal to −8 V.

The value of voltage VG2 is, during the write step, for example positive. The value of voltage VG2 is, during the write step, greater than voltages VG1 and VG1′. The value of voltage VG2 is, during the write step, for example substantially equal to the opposite of the value of voltage VG1. The value of voltage VG2 is, during the write step, for example in the range from 5 V to 10 V, for example substantially equal to 8 V.

Preferably, during the write step, the regions 22 of the cells of said assembly are not biased, that is, are floating, or are biased to the reference voltage, for example, ground.

The different voltages are applied via vias 48, not shown in view 3A.

During the step of erasing of a memory cell 12a, 12b, voltages are applied to said memory cell so that electrons are transferred, by Fowler-Nordheim tunneling effect, from layer 34, where they were stored, to core 26.

In the same way as during the write step, a voltage VG1 is applied to the front gate of the cell from which the data item is erased during this step. In other words, voltage VG1 is applied to the layer 38 of the gate 30a or 30b of the memory cell 12a, 12b from which the data item is erased during this step. Similarly, a voltage VG2 is applied to the back gate of the cell from which the data item is erased during this step. In other words, voltage VG2 is applied to the core 26 of the trench 24 of the memory cell 12a, 12b from which the data item is erased during this step.

Voltage VG1 has, for example, during the erase step, a positive value. For example, voltage VG1, during the erase step, is for example in the range from 5 V to 10 V, for example substantially equal to 8 V.

The value of voltage VG2 is, during the erase step, for example negative. The value of voltage VG2 is, during the erase step, less than voltage VG1. The value of voltage VG2 is, during the erase step, for example substantially equal to the opposite of the value of voltage VG1. The value of voltage VG2 is, during the erase step, for example in the range from −5 V to −10 V, for example substantially equal to −8 V.

Preferably, during the erase step, the regions 22 of the cells of said assembly as well as the front gate of the other cell of the assembly are not biased, that is, are floating, or are biased to the reference voltage, for example, ground.

The different voltages are applied via vias 48, not shown in view 3A.

View 3B is a cross-section view of the device 10 of FIG. 1 along the cross-section plane of view 1C.

During the read step, a current is formed between the source and drain regions of the memory cell to be read, that is, the regions 22 of the memory cell to be read. The value of the current formed depends on the quantity of electrons stored in layer 34 forming the floating gate and thus enables one to determine the cell programming state.

For example, during the read step, voltage VG1 is greater than voltage VG1′. For example, during the read step, voltage VG1 is positive and voltage VG1′ is negative. For example, voltages VG1 and VG1′ are respectively substantially equal to 2 V and −1 V. Further, voltage VG2 is preferably equal to a reference voltage, for example, ground during the read step. A voltage applied to region 20 is preferably equal to a reference voltage, for example ground during the read step.

The regions 22 of the cell to be read are biased so as to form an electric current. For example, one of regions 22 is biased by a positive voltage, for example, substantially equal to 1 V, and the other is biased by the reference voltage, for example, ground.

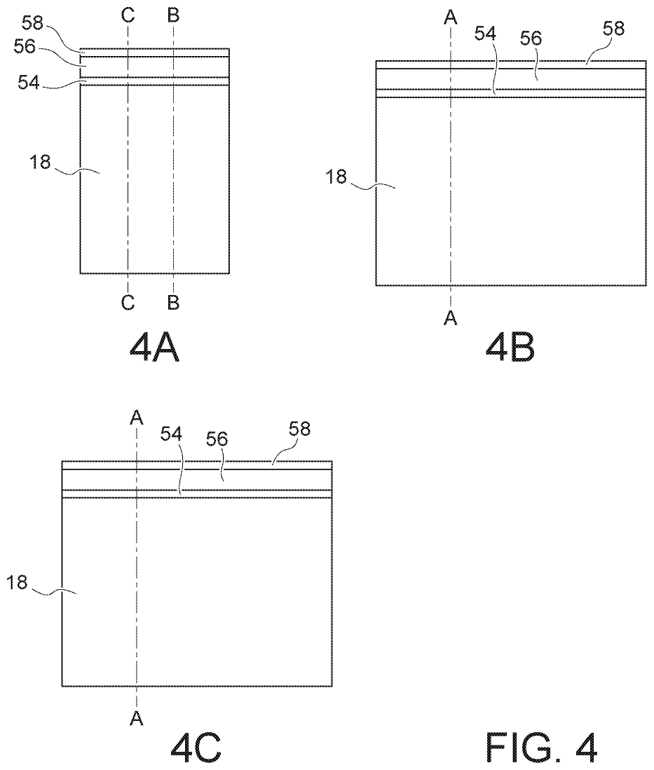

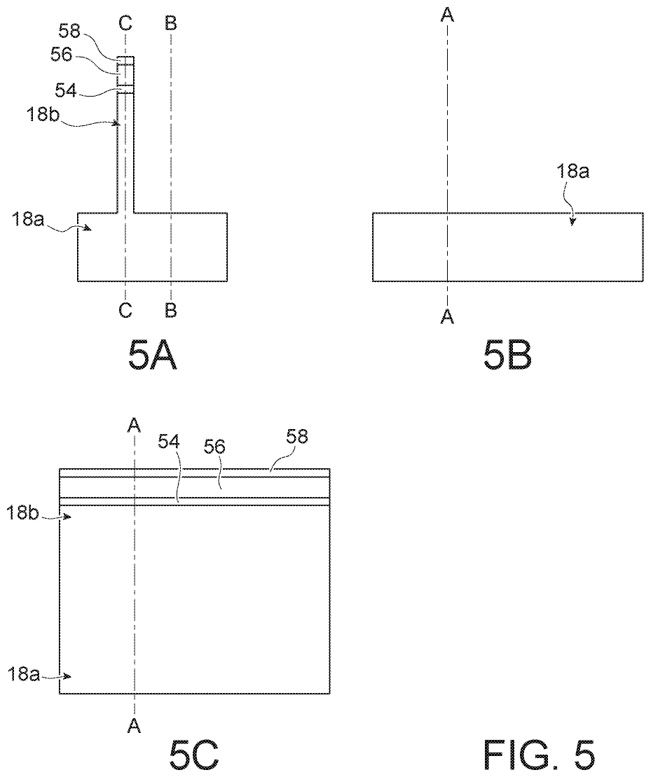

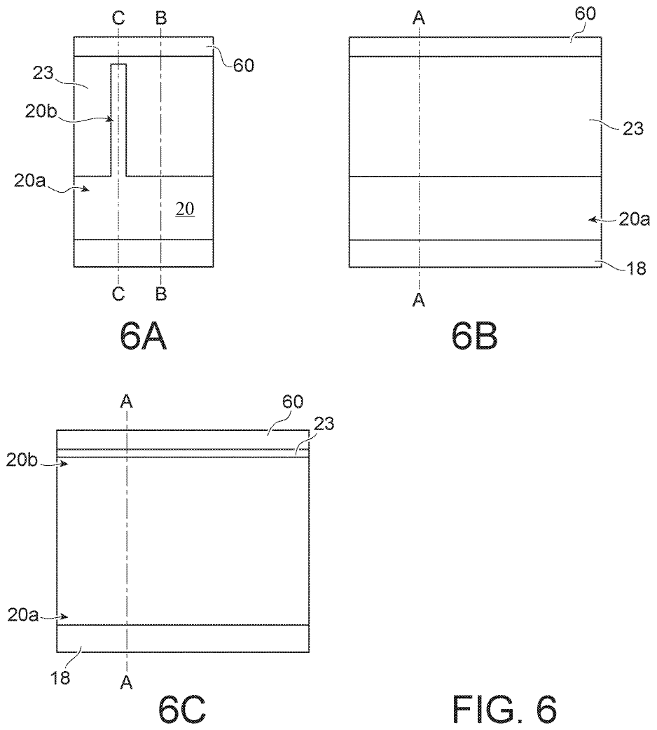

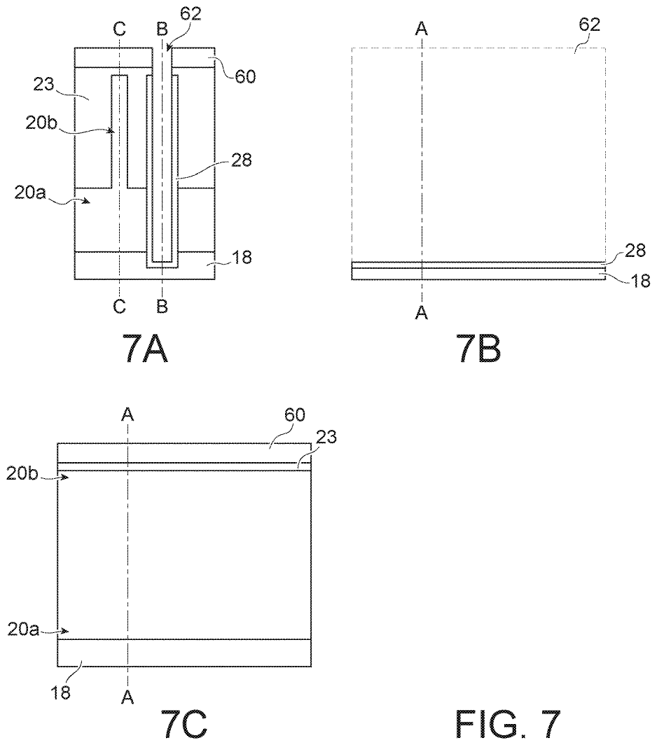

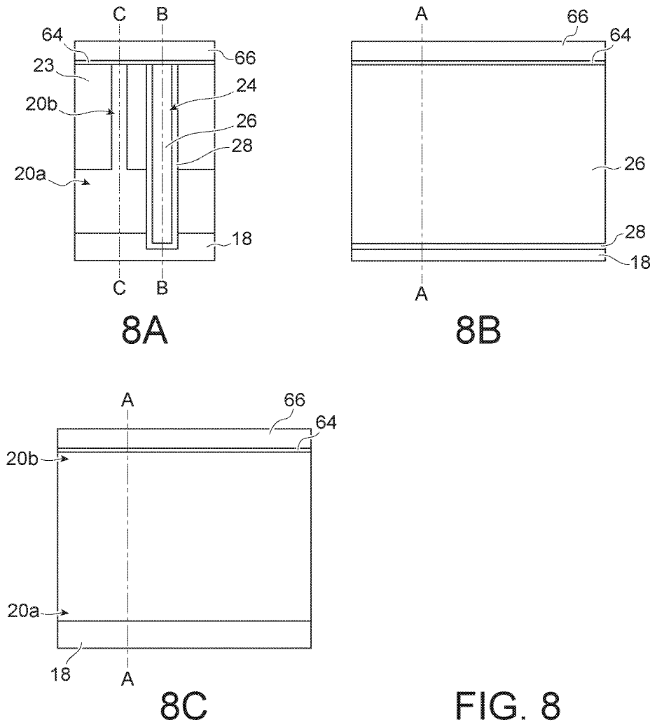

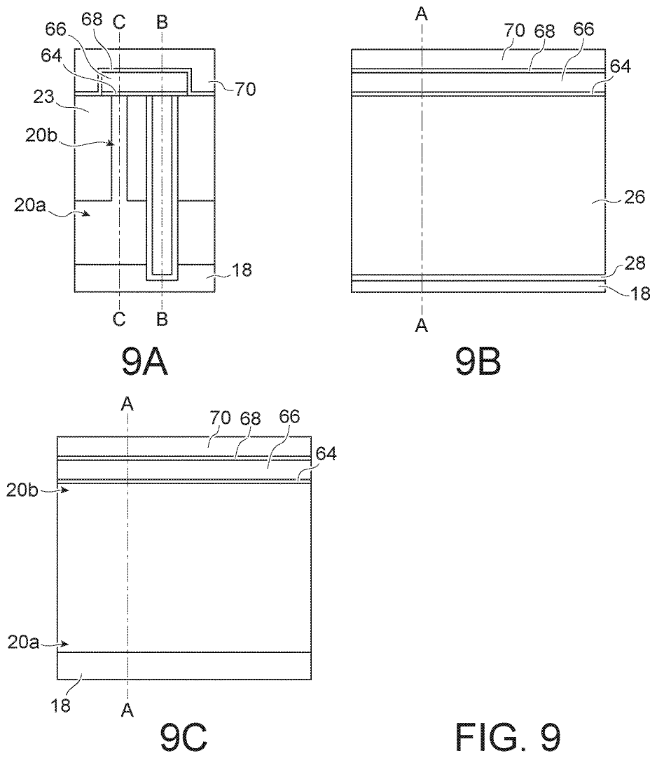

FIG. 4, FIG. 5, FIG. 6, FIG. 7, FIG. 8, FIG. 9, and FIG. 10 show a method of manufacturing the device of FIGS. 1 and 2. More specifically, FIGS. 4 to 10 illustrate structures resulting from steps, preferably successive, of a method of manufacturing the device of FIGS. 1 and 2.

FIG. 4 shows a structure resulting from a step of manufacturing of the device of FIGS. 1 and 2. FIG. 4 comprises cross-section views 4A, 4B, and 4C, respectively along the cross-section planes of views 1A, 1B, and 1C.

During this step, a stack of layers 54, 56, 58 made of dielectric materials is formed on an upper surface of support 18. The stack comprises, in the method of FIGS. 4 to 10, three layers 54, 56, 58. More generally, the stack may have any number of layers.

Preferably, support 18 is a semiconductor wafer. For example, support 18 is made of undoped or P-doped silicon.

Layer 54 is the layer in the stack closest to support 18. Layer 54 extends on top of, and is preferably in contact with, the upper surface of support 18, preferably the entire upper surface of support 18. Layer 54 is for example made of silicon oxide.

Layer 56 extends on top of, and is preferably in contact with, the upper surface of layer 54, preferably the entire upper surface of layer 54. Layer 56 is made of a different material than layer 54, for example of silicon nitride.

Layer 58 extends on top of, and is preferably in contact with, the upper surface of layer 56, preferably with the entire upper surface of layer 56. Layer 58 is made of a material different from the material of layer 56, for example of the material of layer 54, for example of silicon oxide.

FIG. 5 shows a structure resulting from a step of manufacturing of the device of FIGS. 1 and 2. FIG. 5 comprises cross-section views 5A, 5B, and 5C, respectively along the cross-section planes of views 1A, 1B, and 1C.

During this step, support 18 is etched so as to form a first portion 18a, corresponding to the support 18 of FIG. 1 and to the portion 20a of FIG. 1, and a second portion 18b, corresponding to the portion 20b of FIG. 1 and to the regions 22 of FIG. 1.

More specifically, the step of FIG. 5 comprises the forming of an etch mask, not shown, covering the location at which portion 20b and regions 22 will be located. The step of FIG. 5 then comprises the etching of the stack of layers 54, 56, 58 and of support 18 around the etch mask so as to form portions 18a and 18b. The step of FIG. 5 further comprises the removal of the etch mask.

FIG. 6 shows a structure resulting from a step of manufacturing of the device of FIGS. 1 and 2. FIG. 6 comprises cross-section views 6A, 6B, and 6C, respectively along the cross-section planes of views 1A, 1B, and 1C.

During this step, the stack of layers 54, 56, 58 is removed, for example by etching. Further, layer 23 is formed on the structure. Layer 23 is formed so as to cover the upper surface of support 18 and in particular so as to extend at least along the entire height of portion 18b. The upper surface of layer 23 is for example located at a level higher than the level of the upper surface of portion 18b.

In the example of FIG. 6, the upper surface of layer 23 is planar. Alternatively, layer 23 may comprise a cavity, not shown, above portion 18b. The cavity, not shown, preferably has a thickness such that the upper surface of portion 18b is not exposed and remains covered by a portion of layer 23.

The step of FIG. 6 further comprises the forming, for example by doping, of region 20. Thus, P-type dopants are implanted in support 18 so as to form region 20, that is, portions 20a and 20b.

The step of FIG. 6 further comprises, for example, also the forming of a layer 60 made of a dielectric material on the upper surface of the structure. Thus, layer 60 extends on top of, and preferably in contact with, the upper surface of layer 23. Layer 60 is preferably made of a dielectric material different from the material of layer 23, for example of silicon nitride.

FIG. 7 shows a structure resulting from a step of manufacturing of the device of FIGS. 1 and 2. FIG. 7 comprises cross-section views 7A, 7B, and 7C, respectively along the cross-section planes of views 1A, 1B, and 1C.

During this step, a cavity 62 is formed in the structure. Cavity 62 is formed at the location where core 26 will be located. More specifically, the step of FIG. 7 comprises the forming of an etch mask, not shown, comprising an opening located opposite the location where core 26 will be formed. The step of forming of cavity 62 then comprises the etching, through the opening in the mask, of layers 60 and 23, of portion 20a, and of support 18 so as to form cavity 62.

According to the embodiment of FIGS. 4 to 10, cavity 62 does not extend through, and preferably does not expose, portion 20b.

The step of FIG. 7 comprises, for example, the removal of the mask, not shown.

The step of FIG. 7 further comprises the forming of sheath 28. More specifically, the step of FIG. 7 comprises, for example, a step of oxidizing of the walls, that is, the side walls and the bottom, of cavity 62.

FIG. 8 shows a structure resulting from a step of manufacturing of the device of FIGS. 1 and 2. FIG. 8 comprises cross-section views 8A, 8B, and 8C, respectively along the cross-section planes of views 1A, 1B, and 1C.

The step of FIG. 8 comprises the forming of the core 26 of trench 24. More specifically, the step of FIG. 8 comprises, for example, the forming of a layer made of the material of the core filling cavity 62, for example polysilicon, and covering, for example, the entire structure. Said layer is then for example planarized so as to only keep core 26.

The step of FIG. 8 further comprises the removal of layer 60. For example, layer 60 is removed by the planarization step allowing removal of the layer, not shown, made of the material of core 26.

The step of FIG. 8 comprises the forming of a layer 64 made of the material of layers 32, that is, a dielectric material, for example of the same material as layer 23. Layer 64 covers, for example, the upper surface of the structure resulting from the forming of core 26. Thus, layer 64 rests on top of, and is preferably in contact with, the upper surface of layer 23, of portion 20b, and of trench 24, that is, of core 26 and of sheath 28.

The step of FIG. 8 comprises the forming of a layer 66 made of the material of layers 34, that is, of polysilicon. Layer 66 covers, for example, the upper surface of layer 64, preferably the entire layer 64. Thus, layer 66 extends opposite layer 23, portion 20b, and trench 24, that is core 26 and sheath 28.

FIG. 9 shows a structure resulting from a step of manufacturing of the device of FIGS. 1 and 2. FIG. 9 comprises cross-section views 9A, 9B, and 9C, respectively along the cross-section planes of views 1A, 1B, and 1C.

The step shown in FIG. 9 involves the partial etching of layer 66. More specifically, layer 66 is etched to form strips extending in the first direction, that is, the bit line direction. The device preferably comprises one strip per bit line. Each strip formed in layer 66 thus comprises the layers 34 of all the gates of the same bit line. All cells are preferably covered by a strip formed from layer 66.

For example, layers 64 and 66 are etched simultaneously. Each strip then comprises a stack of a strip of layer 64 and of a strip of layer 66, preferably having same horizontal dimensions.

Further, the step of FIG. 9 comprises the forming of a layer 68 made of the material of layers 36, that is, of a dielectric material, for example of the same material as layer 64. Layer 68 covers, for example, the upper surface of the structure resulting from the forming of the strips of layer 66. Thus, layer 68 rests on top of, and is preferably in contact with, the upper surface of layer 23 and the strips of layers 64 and 66.

The step of FIG. 9 comprises the forming of a layer 70 made of the material of layers 38, that is, of polysilicon. Layer 70 covers, for example, the upper surface of layer 68, preferably the entire layer 68.

FIG. 10 shows a structure resulting from a step of manufacturing of the device of FIGS. 1 and 2. FIG. 10 comprises cross-section views 10A, 10B, and 10C, respectively along the cross-section planes of views 1A, 1B and 1C.

The step of FIG. 10 comprises the partial etching of layers 66, 68, and 70. More specifically, the step of FIG. 10 comprises the forming of an etch mask, not shown. Said etch mask comprises strips extending in the word line direction, that is, in the direction perpendicular to the direction of the strips formed in layer 66 during the step of FIG. 9. Each strip of the etch mask thus extends opposite the location of the gates of the memory cell of the same word line.

Layers 66, 68, and 70 are then etched, preferably along their entire height, around the strips of the etch mask so as to form layers 34, 36, and 38.

Layer 64 thus forms further strips extending in the bit line direction. The layers 34 of each cell are separated from one another, layer 66 having been etched in strips in two perpendicular directions. Layers 36 and 38 form strips in the word line direction.

The method of manufacturing the device of FIG. 1 further comprises steps following the steps described in relation with FIG. 10. Thus, the method comprises the forming of spacers 39 and of layer 41, the etching of layer 64 so as to form layers 32 and so as to expose regions 22 at the locations of layer 44, the forming of layers 44 and 40, the forming of layer 46 covering the entire structure, and the forming of conductive vias 48 extending through layer 46 so as to reach layers 44 and 40.

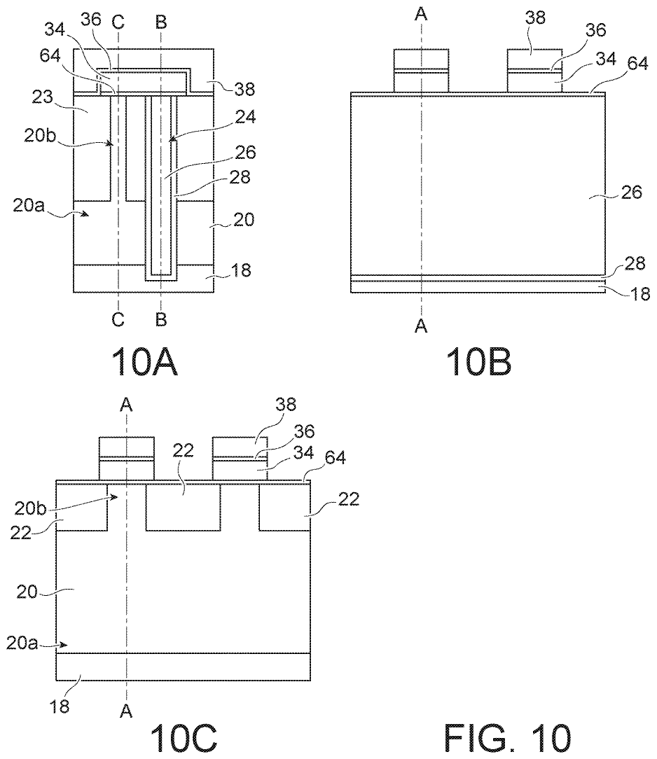

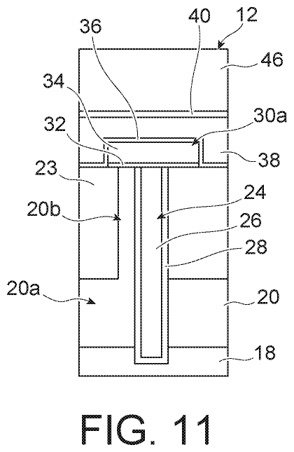

FIG. 11 shows a variant of the embodiment of FIGS. 1 and 2. More specifically, FIG. 11 is a cross-section view of a variant of the embodiment of FIG. 1 along the cross-section plane of view 1A.

FIG. 11 shows a device 72 comprising the elements of the device 10 of FIG. 1. Device 72 comprises, like the device 10 of FIG. 1, assemblies of two memory cells, for example arranged in an array in a memory region, although FIG. 11 shows a single memory cell of the assembly. Device 72 comprises, like the device 10 described in relation with FIG. 1:
support 18,
layer 20 comprising portions 20a and 20b,
layer 23, the trench 24 of each cell comprising core 26 and sheath 28,
a gate of each cell, comprising layers 32, 34, 36, 38,
metal silicide layers 40 and 44;
layer 46 for protecting the structure, and
vias 48.

Device 72 differs from device 10 in that trench 24 is formed at an interface between portion 20b and layer 23. In other words, trench 24 is located between portion 20b and layer 23. Thus, the core 26 of trench 24 is separated from portion 20b by sheath 28 only.

The method of manufacturing the device of FIG. 11 is identical to that described in relation with FIGS. 4 to 10, with the difference that at the step of FIG. 7, cavity 62 is located at the interface between portion 20b and layer 23. Thus, during this step, the walls of cavity 62 are formed by portion 20b, layer 23, portion 20a, and support 18.

An advantage of the described embodiments is that the memory cells are more compact, and it is thus possible to form the cells more densely.

Another advantage of the described embodiments is that it is not necessary to differentiate read and write oxides

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given above.

What is claimed is:

1. A device comprising at least one memory cell, the memory cell comprising:
an active area made of a semiconductor material, the active area comprising source and drain regions;
a first selection gate made of a semiconductor material, the first selection gate extending parallel to the active area and being separated from the active area by a first layer made of a dielectric material; and
a second measurement gate resting on the source and drain regions and on the first selection gate.

2. The device according to claim 1, wherein the upper surfaces of the source and drain regions are coplanar with an upper surface of the active area and that the first selection gate is laterally separated from the active area by a first layer made of a dielectric material.

3. The device according to claim 1, wherein the first selection gate is made of polysilicon.

4. The device according to claim 1, wherein the first selection gate and the active area are separated only by the first layer made of a dielectric material.

5. The device according to claim 1, wherein the second measurement gate comprises:
a second layer made of a dielectric material;
a first layer made of a semiconductor material disposed on the second layer;
a third layer made of an insulating material disposed on the first layer made of a semiconductor material; and
a second layer made of a semiconductor material disposed on the third layer.

6. The device according to claim 5, wherein the second layer made of a dielectric material is in contact with the first selection gate and with the active area.

7. The device according to claim 1, wherein the device comprises at least two memory cells having a source or drain region in common.

8. The device according to claim 1, wherein the first selection gate is configured to store electrons transferred from the second measurement gate by Fowler-Nordheim tunneling effect during a write operation, and wherein the first selection gate is configured to transfer electrons to the second measurement gate by Fowler-Nordheim tunneling effect during an erase operation.

9. A device comprising:
a support made of a semiconductor material;
a semiconductor region disposed on the support, the semiconductor region comprising a lower portion and an upper portion extending from the lower portion, the upper portion forming a wall extending in a first direction;
a dielectric layer surrounding side walls of the upper portion;
a trench extending through the dielectric layer, the lower portion, and into the support, the trench comprising a core made of a semiconductor material and a sheath made of a dielectric material covering a lower surface and lateral surfaces of the core, the trench extending parallel to the upper portion;
at least two memory cells, each memory cell comprising:
source and drain regions disposed in the upper portion, the source and drain regions being doped with a conductivity type opposite to a conductivity type of the semiconductor region; and
a gate disposed on the upper portion and on the trench, the gate comprising:
a first dielectric layer in contact with an upper surface of the upper portion and an upper surface of the trench;
a floating gate layer made of a semiconductor material disposed on the first dielectric layer;
a second dielectric layer disposed on the floating gate layer; and
a contact gate layer made of a conductive or semiconductor material disposed on the second dielectric layer;
wherein the at least two memory cells share a common source or drain region; and
wherein the core of the trench is configured to be biased during programming steps of the at least two memory cells.

10. The device according to claim 9, wherein the memory cells are arranged in an array of rows and columns.

11. The device according to claim 9, wherein the trench is separated from the upper portion by a portion of the dielectric layer.

12. The device according to claim 9, wherein the trench is located at an interface between the upper portion and the dielectric layer such that the core of the trench is separated from the upper portion by the sheath only.

13. The device according to claim 9, wherein the second dielectric layer comprises a stack of a silicon oxide layer, a silicon nitride layer, and a silicon oxide layer.

14. A method of manufacturing a device comprising at least one memory cell, the method comprising:
forming an active area made of a semiconductor material, the active area comprising source and drain regions;
forming a first selection gate made of a semiconductor material, the first selection gate extending parallel to the active area and being separated from the active area by a first layer made of a dielectric material; and
forming a second measurement gate resting on the source and drain regions and on the first selection gate.

15. The method according to claim 14, wherein forming the first selection gate comprises:
forming a cavity at a location of the first selection gate; and
forming the first layer made of a dielectric material along side walls and a bottom of the cavity by oxidation.

16. The method according to claim 14, wherein forming the active area comprises:
forming a stack of dielectric layers on an upper surface of a semiconductor support;
etching the semiconductor support through the stack of dielectric layers to define a first portion and a second portion of the semiconductor support, the second portion forming a wall extending in a first direction; and
removing the stack of dielectric layers and forming a dielectric layer surrounding side walls of the second portion.

17. The method according to claim 14, wherein forming the second measurement gate comprises:
forming a first dielectric layer on an upper surface of the active area and on an upper surface of the first selection gate;
forming a first semiconductor layer on the first dielectric layer;
patterning the first semiconductor layer into strips extending in a first direction;
forming a second dielectric layer on the strips of the first semiconductor layer;
forming a second semiconductor layer on the second dielectric layer; and
patterning the first semiconductor layer, the second dielectric layer, and the second semiconductor layer in a second direction perpendicular to the first direction to define individual gates for each memory cell.

18. The method according to claim 17, wherein the patterning in the second direction separates the first semiconductor layer into individual floating gates for each memory cell while the second semiconductor layer and the second dielectric layer form strips common to a plurality of memory cells in the second direction.

19. The method according to claim 14, further comprising:
forming metal silicide layers on the source and drain regions, on the first selection gate, and on the second measurement gate;
forming an insulating layer covering the memory cell; and
forming conductive vias extending through the insulating layer to reach the metal silicide layers.

20. The method according to claim 14, wherein the upper surfaces of the source and drain regions are coplanar with an upper surface of the active area and that the first selection gate is laterally separated from the active area by a first layer made of a dielectric material.
